(19) United States
(12) Patent Application Publication
(10) Pub. No.: US 2014/0291598 A1
(43) Pub. Date: Oct. 2, 2014

(54) RESISTIVE RANDOM ACCESS MEMORY

(71) Applicant: Intellectual Discovery Co., Ltd., Seoul (KR)

(72) Inventor: Hyun Sang Hwang, Pohang-si (KR)

(73) Assignee: Intellectual Discovery Co., Ltd., Seoul (KR)

(21) Appl. No.: 14/227,038

(22) Filed: Mar. 27, 2014

(30) Foreign Application Priority Data
Mar. 28, 2013 (KR) 10-2013-0033641

(51) Int. Cl. H01L 45/00

(52) U.S. Cl. CPC H01L 45/1266; H01L 45/08
USPC 257/2

(57) ABSTRACT

Disclosed is a nonvolatile resistive random access memory. The nonvolatile resistive random access memory includes an upper electrode, a lower electrode, an ion supply layer formed on the lower electrode, and a resistance change layer formed on the ion supply layer. The ion supply layer includes copper-doped carbon. A low-power switching operation is performed because the optimal filament is formed by limiting the number of supplied ions, without using the existing method that supplies infinite ions by using a metal electrode.

### CROSS-REFERENCE TO RELATED APPLICATIONS

This application claims priority under 35 U.S.C. §119 to Korean Patent Application No. 10-2013-0033641, filed on Mar. 28, 2013, the disclosure of which is incorporated herein by reference in its entirety.

### TECHNICAL FIELD

The present invention relates to a memory, and more particularly, to a nonvolatile resistive random access memory (ReRAM).

### BACKGROUND

Recently, researched is being done for next-generation nonvolatile memories that have lower power consumption and a higher degree of integration than flash memories. Examples of the next-generation nonvolatile memories include phase change RAMs (PRAMs) that use a state change of a phase change material such as an chalcogenide alloy, magnetic RAMs that use a resistance change of a magnetic tunnel junction (MTJ) thin film based on a magnetization state of a ferromagnetic material, ferroelectric RAMs that use a polarization of a ferroelectric material, and ReRAMs that use a resistance change of a variable resistance material.

In the memories, the ReRAMs include a resistance change memory cell that includes an upper electrode, and a lower electrode, and a variable resistance material formed therebetween. The ReRAMs have a characteristic in which a resistance of the variable resistance material is changed according to voltages respectively applied to the upper electrode and the lower electrode.

After the ReRAM is manufactured, by applying a very high level of filament formation voltage to the resistance change memory cell, a filament is formed in the variable resistance material.

The filament is a current path of a cell current that flows between the upper electrode and the lower electrode. After the filament is formed, the variable resistance material may be reset by applying a reset voltage, or the variable resistance material may be set up by applying a setup voltage.

The ReRAMs have a filament-type switching mechanism, and thus have a fast switching characteristic, a stable retention characteristic, etc. However, due to a randomly formed filament, it is difficult to fundamentally secure a stable switching characteristic.

Moreover, the ReRAMs should operate at a fast speed under a program voltage, and have ten-year data retention in a read mode. However, it is difficult to simultaneously satisfy the two conditions by using current technology.

To this end, technology has been developed in which two switches are connected in series, and a desired program speed and a desired data retention are secured by parallelly programming the two switches. In this case, however, a structure of a device becomes complicated, and an area of the device increases.

FIG. 1 is a view illustrating a structure and operation characteristic of a general PMC device. As illustrated in FIG. 1, the general PMC device includes a metal electrode formed of copper (Cu), a metal electrode formed of ruthenium (Ru), and an ion conducting layer formed therebetween.

The PMC device allows a current to flow into a nonconductive material and prevents the current from flowing to the nonconductive material by using an electrolyte characteristic of an amorphous chalcogenide material, thereby generating a signal of 0 and a signal of 1. In the PMC device, a part in which switching of a voltage is performed is formed by light-doping silver (Ag) or Cu on an amorphous chalcogenide combination, and Ag or Cu ions receiving energy generated by irradiated light penetrate into a chalcogenide thin film, and are located at defects of the chalcogenide thin film.

The Ag or Cu ions uniformly distributed on the chalcogenide thin film are changed to superionic conductors, thereby generating a compound. The compound has a high ion conductivity corresponding to a melt solution in a solid state when reaching a specific temperature.

The conductive metal ions doped on the thin film act with the internal defects of the thin film, thereby allowing a current to pass through a high-resistance amorphous chalcogenide thin film. A characteristic, in which the conductive metal ions allow a current to flow and prevent the current from flowing, is similar to a characteristic of an electrolyte, and thus, each of the conductive metal ions is called a solid electrolyte.

To briefly describe an operation mechanism of the PMC device, positive (+) Cu ions are moved to a cathode by an applied voltage, and thus, Cu⁺ ions start to be accumulated from the cathode, and are continuously accumulated upward, thereby forming a fine conduction pathway that connects a lower electrode and an upper electrode.

A rapid reduction in a resistance due to the formation of the conduction pathway maintains a turn-on state of a memory, and when the applied voltage is reversely biased, the Cu⁺ ions are separated from the conduction pathway and are changed to high-resistance resistors that prevent a current from flowing, thereby maintaining a turn-off state.

In the general PMC device, in terms of the number of atoms, infinite metal ions are supplied, and for this reason, it is difficult to control a filament that is a current path.

Moreover, switching of the PMC device is performed by movement of ions that is performed a voltage bias applied to both electrodes and Joule heating. Generally, activation energy necessary for movement of ions is 1 eV or less. For this reason, it is difficult to simultaneously satisfy a high-temperature retention and a fast switching speed.

### SUMMARY

Accordingly, the present invention provides an ReRAM that performs a low-power switching operation because the optimal filament is formed by limiting the number of supplied ions, without using the existing method that supplies infinite ions by using a metal electrode.

The present invention also provides an ReRAM in which a metal oxide layer for controlling a mobility of ions is additionally provided, thereby improving a retention characteristic of a device.

The object of the present invention is not limited to the aforesaid, but other objects not described herein will be clearly understood by those skilled in the art from descriptions below.

In one general aspect, a resistive random access memory (ReRAM) includes: an upper electrode; a lower electrode; an ion supply layer formed on the lower electrode; and a resistance change layer formed on the ion supply layer, wherein the ion supply layer includes copper-doped carbon.

The ion supply layer may include at least one of CuₓC_{y} (0.35<x<0.7), CuₓMoO_{y} (0.35<x<0.7), and copper-doped Ge₂Sb₂Te₅.

The resistance change layer may include at least one of SiO₂₋ₓ, Al₂O₃₋ₓ, Ta₂O₅₋ₓ, TiO₂₋ₓ, HfO₂₋ₓ, and ZrO₂₋ₓ.

The resistance change layer may include multi oxide thin films, at least one of the multi oxide thin films having activation energy of at least 2 eV or more necessary for movement of ions.

The resistance change layer may include: a first insulation layer configured to include at least one of SiO₂, Al₂O₃, Ta₂O₅, TiO₂, HfO₂, and ZrO₂; and a second insulation layer configured to include at least one of SiO₂₋ₓ, Al₂O₃₋ₓ, Ta₂O₅₋ₓ, TiO₂₋ₓ, HfO₂₋ₓ, and ZrO₂₋ₓ.

The first insulation layer may have activation energy of at least 2 eV or more necessary for movement of ions.

Other features and aspects will be apparent from the following detailed description, the drawings, and the claims.

### BRIEF DESCRIPTION OF THE DRAWINGS

FIG. 1 is a view illustrating a structure and operation characteristic of a general PMC device.

FIG. 2 is a view illustrating a cross-sectional surface of a memory according to an embodiment of the present invention.

FIG. 3 is a view illustrating a cross-sectional surface of a memory according to another embodiment of the present invention.

FIG. 4 is a diagram for describing an improved effect of the memory according to an embodiment of the present invention.

FIG. 5 is a diagram for describing a switching characteristic based on a concentration of copper according to an embodiment of the present invention.

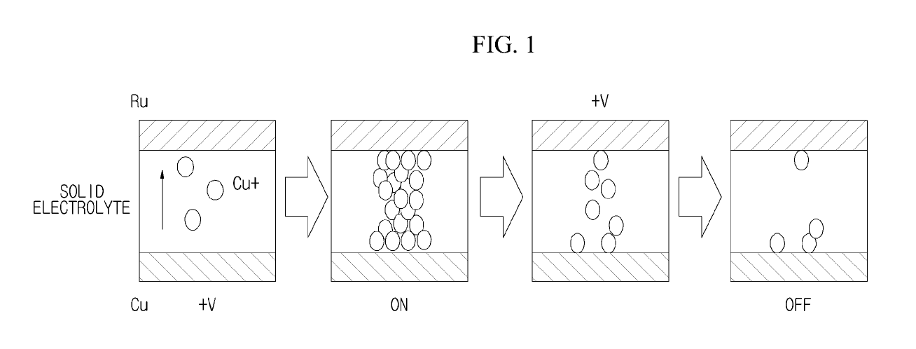

### DETAILED DESCRIPTION OF EMBODIMENTS

Advantages and features of the present invention, and implementation methods thereof will be clarified through following embodiments described with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Further, the present invention is only defined by scopes of claims. In the following description, the technical terms are used only for explaining a specific exemplary embodiment while not limiting the present invention. The terms of a singular form may include plural forms unless specifically mentioned.

Hereinafter, exemplary embodiments of the present invention will be described in detail with reference to the accompanying drawings. In adding reference numerals for elements in each figure, it should be noted that like reference numerals already used to denote like elements in other figures are used for elements wherever possible. Moreover, detailed descriptions related to well-known functions or configurations will be ruled out in order not to unnecessarily obscure subject matters of the present invention.

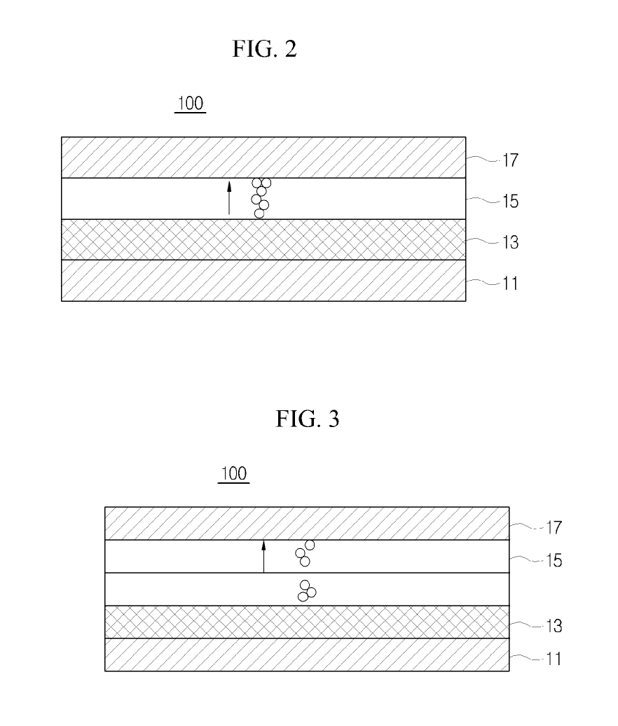

FIG. 2 is a view illustrating a cross-sectional surface of a memory 100 according to an embodiment of the present invention. As illustrated in FIG. 2, the memory 100 according to an embodiment of the present invention includes a lower electrode 11, an ion supply layer 13, a resistance change layer 15, and an upper electrode 17.

Referring to FIG. 2, the lower electrode 11 is disposed on a substrate 10. The substrate 10 may be a silicon substrate or a silicon-on insulator (SOI) substrate. According to embodiments, a specific layer may be disposed between the substrate 10 and the lower electrode 11.

The lower electrode 11 may be a platinum (Pt) layer, a Ru layer, an iridium (Ir) layer, or an aluminum (Al) layer. The lower electrode 11 may include a conductive material, and for example, may include a material that achieves an ohmic-junction with the ion supply layer 13.

The upper electrode 17 facing the lower electrode 11 may be disposed on the lower electrode 11. The upper electrode 17 may be a Pt layer, a tungsten (W) layer, or a molybdenum (Mo) layer.

The ion supply layer 13 may be disposed between the lower electrode 11 and the upper electrode 17. The ion supply layer 13 generates diffusive ions with a bias voltage applied between the lower electrode 11 and the upper electrode 17.

For example, the ion supply layer 13 may use an electrolyte containing metal ions having the optimal concentration. Instead of a metal electrode that generally acts as an ion supply source, the ion supply layer 13 limits supplied ions, and thus, a filament is formed by a minimum of ions.

In detail, the ion supply layer 13 may use a Cu-doped carbon layer as an electrolyte. The ion supply layer 13 may be formed of at least one of CuₓC_{y} (0.35<x<0.7), CuₓMoO_{y} (0.35<x<0.7), and Cu-doped Ge₂Sb₂Te₅.

Here, various switching characteristics may be secured depending on a concentration of Cu. That is, when a concentration of Cu is low (X=0.2), as illustrated in FIG. 5, threshold switching is shown. On the other hand, when a concentration of Cu is high (X=0.78), a thick filament is formed, and a high current is needed in reset. That is, it can be seen that Cu having a suitable concentration is needed for forming a filament having a suitable size.

In the present embodiment, a concentration of Cu forming the ion supply layer 13 is 0.35 to 0.7. As described above, the ReRAM according to the present embodiment has a good switching characteristic in a limited numerical range.

The resistance change layer 15 is formed on the ion supply layer 13. The resistance change layer 15 may directly contact the ion supply layer 13.

The resistance change layer 15 may be a single crystalline layer, an epitaxy layer, a multi-crystalline layer, or an amorphous layer. A yield rate of devices is good when the resistance change layer 15 is the multi-crystalline layer or the amorphous layer in addition to the single crystalline layer or the epitaxy layer. However, the resistance change layer 15 having a large area is more uniform when the resistance change layer 15 is the multi-crystalline layer or the amorphous layer than when the resistance change layer 15 is the single crystalline layer or the epitaxy layer. Therefore, the resistance change layer 15 may be the multi-crystalline layer or the amorphous layer.

For example, the resistance change layer 15 may be formed of at least one of SiO₂₋ₓ, Al₂O₃₋ₓ, Ta₂O₅₋ₓ, TiO₂₋ₓ, HfO₂₋ₓ, and ZrO₂₋ₓ.

The resistance change layer 15 may be formed by a physical vapor deposition (PVD) process, such as a sputtering process, a pulsed layer deposition (PLD) process, a thermal evaporation process, or an electron-beam evaporation process, a molecular beam epitaxy (MBE) process, or a chemical vapor deposition (CVD) process.

FIG. 3 is a view illustrating a cross-sectional surface of a memory 100 according to another embodiment of the present invention. As illustrated in FIG. 3, in the memory 100 according to another embodiment of the present invention, the resistance change layer 15 may be formed of multi oxide thin films.

For example, the resistance change layer 15 may include a first insulation layer, which includes at least one of SiO₂, Al₂O₃, Ta₂O₅, TiO₂, HfO₂, and ZrO₂, and a second insulation layer that includes at least one of SiO₂₋ₓ, Al₂O₃₋ₓ, Ta₂O₅₋ₓ, TiO₂₋ₓ, HfO₂₋ₓ, and ZrO₂₋ₓ.

In particular, an insulator thin film that is very thin and has a suitable composition ratio is additionally provided, and thus, only when a sufficient tunneling current flows under a high electric field, ions move in the resistance change layer 15 to effect switching. Under a low electric field, movement of ions is limited, and a data retention characteristic is secured.

Moreover, at least one of a plurality of insulator thin films configuring the resistance change layer 15 has activation energy of at least 2 eV or more necessary for movement of ions.

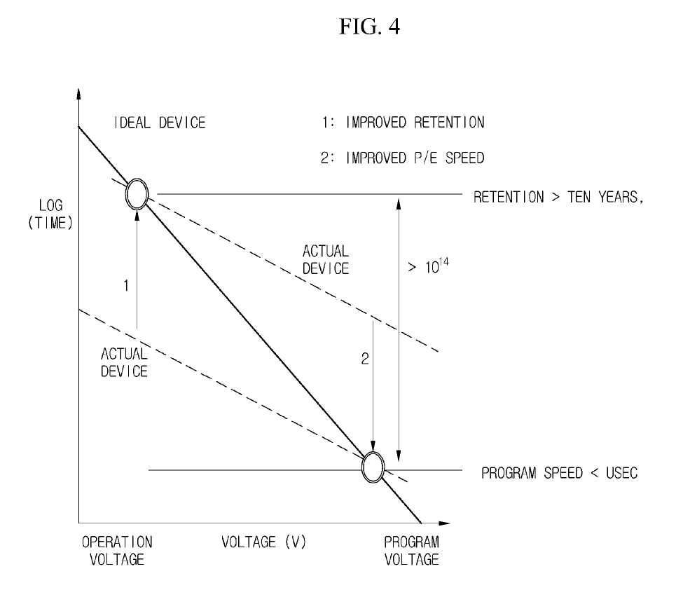

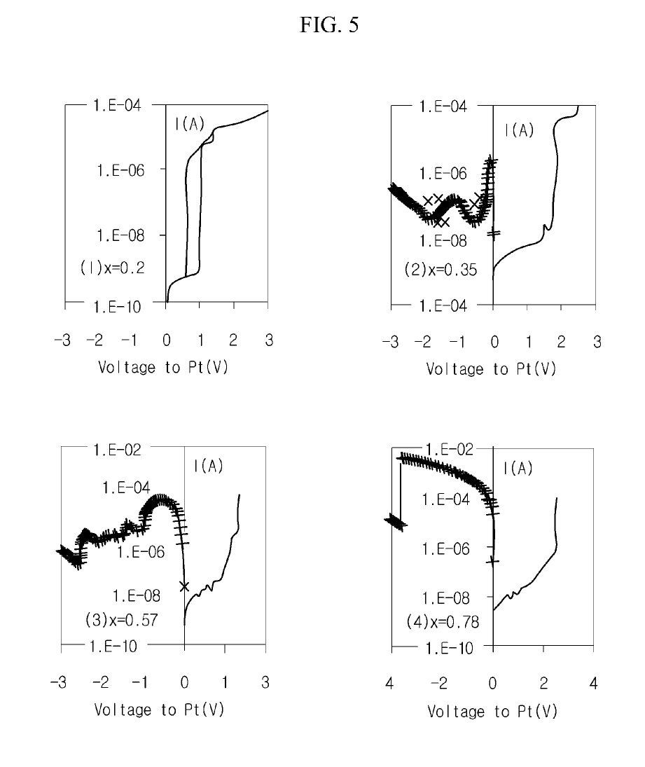

FIG. 4 is a diagram for describing an improved effect of the memory according to an embodiment of the present invention.

Referring to FIG. 4, in the memory according to an embodiment of the present invention, it can be seen that a program speed and a data retention characteristic are improved. In actual devices, the program speed (a switching operation speed) and the data retention (a durability of a memory) characteristic have a mutual tradeoff relationship, namely, have a relationship in which a durability of a memory is reduced when the switching operation speed characteristic is improved, and when the durability of the memory is improved, the switching operation speed is reduced.

According to the embodiments of the present invention, instead of a metal electrode, the ion supply layer that supplies ions forms a filament at the optimal concentration to enable a switching operation to be performed under a low current, thereby improving the switching operation speed (see 2 of FIG. 4). Also, among multi oxide thin films configuring the resistance change layer, the tunneling barrier that has activation energy of at least 2 eV or more necessary for movement of ions adjusts a degree of ion diffusion, thereby improving a durability of a device (see 1 of FIG. 4).

As described above, according to the present invention, since the tunneling bather for controlling mobility is additionally provided, a tunneling current is exponential-functionally changed according to an applied voltage, and thus, a mobility of ions is exponential-functionally changed according to the applied voltage.

Moreover, at least one or more insulation layers for obstructing ion conduction are inserted into the resistance change layer, thereby securing a stable data retention characteristic of a device. That is, by using a multi-layer thin film structure having different degrees of ion diffusion, a speed can be secured under a high voltage, and moreover, a data retention characteristic can be secured under a low voltage.

Moreover, a low-power switching operation is performed because the optimal filament is formed by limiting the number of supplied ions, without using the existing method that supplies infinite ions by using a metal electrode.

A number of exemplary embodiments have been described above. Nevertheless, it will be understood that various modifications may be made. For example, suitable results may be achieved if the described techniques are performed in a different order and/or if components in a described system, architecture, device, or circuit are combined in a different manner and/or replaced or supplemented by other components or their equivalents. Accordingly, other implementations are within the scope of the following claims.

What is claimed is:

1. A resistive random access memory (ReRAM) comprising:
an upper electrode;
a lower electrode;
an ion supply layer formed on the lower electrode; and
a resistance change layer formed on the ion supply layer,
wherein the ion supply layer comprises copper-doped carbon.

2. The ReRAM of claim 1, wherein the ion supply layer comprises at least one of CuₓC_{y} (0.35<x<0.7), CuₓMoO_{y} (0.35<x<0.7), and copper-doped Ge₂Sb₂Te₅.

3. The ReRAM of claim 1, wherein the resistance change layer comprises at least one of SiO₂₋ₓ, Al₂O₃₋ₓ, Ta₂O₅₋ₓ, TiO₂₋ₓ HfO₂₋ₓ, and ZrO₂₋ₓ.

4. The ReRAM of claim 1, wherein the resistance change layer comprises multi oxide thin films, at least one of the multi oxide thin films having activation energy of at least 2 eV or more necessary for movement of ions.

5. The ReRAM of claim 1, wherein the resistance change layer comprises:
a first insulation layer configured to include at least one of SiO₂, Al₂O₃, Ta₂O₅, TiO₂, HfO₂, and ZrO₂; and
a second insulation layer configured to include at least one of SiO₂₋ₓ, Al₂O₃₋ₓ, Ta₂O₅₋ₓ, TiO₂₋ₓ, HfO₂₋ₓ, and ZrO₂₋ₓ.

6. The ReRAM of claim 5, wherein the first insulation layer has activation energy of at least 2 eV or more necessary for movement of ions.
